(19) United States
(12) Patent Application Publication
(10) Pub. No.: US 2013/0092527 A1
(43) Pub. Date: Apr. 18, 2013

(54) Method for Manufacturing Shielding

(71) Applicants: Yau-Hung Chiou, Taipei City (TW); Chao-Lun Liu, Taipei City (TW); Shu-Hui Fan, Guanxi Township (TW)

(72) Inventors: Yau-Hung Chiou, Taipei City (TW); Chao-Lun Liu, Taipei City (TW); Shu-Hui Fan, Guanxi Township (TW)

(73) Assignee: CHENMING MOLD IND. CORP., Taipei City (TW)

(21) Appl. No.: 13/325,912

(22) Filed: Dec. 14, 2011

(30) Foreign Application Priority Data
Oct. 14, 2011 (TW) 100137252

(51) Int. Cl. C23C 14/34

(52) U.S. Cl. 204/192.3

(57) ABSTRACT

A method for manufacturing shielding which uses multiple vacuum sputtering methods to produce shielding on single IC chip. The method comprises the following steps: using covering fixtures to cover a plurality of IC chips and fixing these IC chips on a work support; vacuumizing the chamber to a pretreatment vacuum level; keeping pumping an ionizable gas into the chamber and performing ion bombardment on the material for IC packaging on the surface of these IC chips in order to produce carbon dangling bond connection layer on the material when the vacuum level of the chamber reaches the work vacuum level; performing multiple vacuum sputtering method to sequentially form a first coating layer, a second coating layer and a third coating layer on the carbon dangling bond connection layer; and breaking the vacuum status of the chamber and taking out the coated IC chips.

### CROSS-REFERENCE TO RELATED APPLICATION

This application claims the benefit of Taiwan Patent Application No. 100137252, filed on Oct. 14, 2011, in the Taiwan Intellectual Property Office, the disclosure of which is incorporated herein in its entirety by reference.

### BACKGROUND OF THE INVENTION

1. Field of the Invention

The present invention generally relates to a method for manufacturing shielding, in particular to a method for manufacturing shielding on single IC chip by multiple vacuum sputtering methods.

2. Description of the Related Art

With advances in science and technology, electronic products are becoming smaller in size as well as more and more powerful, such that complexity and density of integrated circuit (IC) inside the electronic products are increasing day by day. As electromagnetic wave is emitted by conducting wires, power inside ICs or high-frequency electronic components on a circuit board, the other components on the circuit board are apt to be influenced by electromagnetic interference (EMI) and cannot work normally. Accordingly, how to reduce EMI from circuit boards has become an important issue to be solved.

Generally speaking, a metal shell is usually used to cover over part of a traditional printed circuit board in order to prevent EMI from circuit boards. As shown in FIG. 1, a metal shell 11 covers over an IC chip 12 to prevent a circuit board 1 from EMI. However, an independent manufacturing procedure is needed for metal shell 11 and additional manpower cost is needed for assembling the metal shell 11 to the circuit board 1, which means high cost. In addition, the metal shell 11 is usually welded to the circuit board 1 or fixed on the circuit board 1 by other ways, which increases the size of the circuit board 1. A user has to disassemble the metal shell 11 from the circuit board 1 in order to replace or repair the IC chip 12, which is inconvenient for the user and inclined to damage the circuit board 1. Besides, the metal shell 11 causes serious thermal dissipation problem.

FIG. 2 shows another common IC shielding layer. In the embodiment, a shielding layer 21 is formed on a circuit board 2 with a plurality of IC chips. In this way, an additional manufacturing procedure for the shielding layer 21 has to be added to the manufacturing procedure for the circuit board 2, which changes the original manufacturing procedure for the circuit board 2 and results in inconveniency. In addition, the shielding layer 21 covering over the plurality of IC chips must be formed at a same time and the plurality of IC chips attached on the circuit board needs to be divided into single IC chips thereafter. As the shielding layer 21 cannot be formed on a single IC chip, the method of the embodiment is not flexible. Thus, the present invention provides a method for manufacturing IC shielding layer to improve the problem that the prior-art metal shell is heavy, high-cost and unfavorable to thermal dissipation, and the problem that the prior-art method for forming IC shielding layer on a plurality of IC chips is not convenient and flexible.

### SUMMARY OF THE INVENTION

Therefore, it is a primary objective of the present invention to provide a method for manufacturing shielding to resolve the problems that the prior-art metal shell is heavy, high-cost and unfavorable to thermal dissipation, and the problem that the prior-art method for forming IC shielding layer on a plurality of IC chips attached on a circuit board is not convenient and flexible.

To achieve the foregoing objective, the present invention provides a method for manufacturing shielding. The method comprises the following steps: covering a plurality of integrated circuit (IC) chips by covering fixtures and fixing the plurality of IC chips to a work support; vacuumizing a chamber to a pretreatment vacuum level; keeping pumping an ionizable gas into the chamber and performing ion bombardment on the material for IC packaging on the surface of the plurality of ICs in order to produce a carbon dangling bond connection layer on the material when the vacuum level of the chamber reaches a work vacuum level; performing multiple vacuum sputtering methods to form a first coating layer and a second coating layer on the carbon dangling bond connection layer; and breaking the vacuum status of the chamber and removing the coated IC chips.

In an embodiment, the multiple vacuum sputtering methods may comprise the middle frequency sputtering, the direct current (DC) sputtering or the multi-arc ion plating.

In an embodiment, the first coating layer may be a metal bonding layer formed by the middle frequency sputtering or the multi-arc ion plating.

In an embodiment, the second coating layer may be a metal shielding layer formed by the middle frequency sputtering or the multi-arc ion plating.

In an embodiment, the metal shielding layer may be formed by a mixed sputtering which alternates the middle frequency sputtering and the multi-arc ion plating.

In an embodiment, the mixed sputtering may comprise mixedly sputtering metal and non-mental, mixedly sputtering metals with different grain sizes and mixedly sputtering two different metals.

In an embodiment, the third coating layer may be an antioxidant layer formed by the DC sputtering or the middle frequency sputtering.

In an embodiment, the ionizable gas may be argon (AR).

In an embodiment, the pretreatment vacuum level may be 1×10⁻⁵ Torr.

In an embodiment, the work vacuum level may be 1×10⁻³˜10⁻⁴ Torr.

The method for manufacturing shielding according to the present invention has the following advantages:

(1) The method for manufacturing shielding according to the present invention is to directly form IC shielding layer on an IC chip. Thus, the present invention can resolve the problems that the prior-art metal shell is heavy, high-cost and unfavorable to thermal dissipation.

(2) The method for manufacturing shielding according to the present invention is to directly form IC shielding layer on an IC chip. Thus, the method according to the present invention can resolve the problems that the prior-art method needs to add an independent manufacturing procedure to the manufacturing procedure for the circuit board in order to form IC shielding layer on a plurality of IC chips attached on the circuit board. Thus, the method according to the present invention is more convenient and flexible.

(3) The method for manufacturing shielding according to the present invention can resolve the problem that the prior-art method needs to perform a “pre-cutting” process on a circuit board having a plurality shielded IC chips. Thus, the method according to the present invention is much simpler.

(4) The method for manufacturing shielding according to the present invention can form multiple layers with different effects at a time, such as EMI shielding layer or protective layer, etc.

(5) The method for manufacturing shielding according to the present invention can perform multiple physical vapor deposition processes with an equipment, such like ion bombardment, biasing voltage, the DC sputtering, the middle frequency sputtering or the multi-arc ion plating, etc.

### BRIEF DESCRIPTION OF THE DRAWINGS

The detailed structure, operating principle and effects of the present invention will now be described in more details hereinafter with reference to the accompanying drawings that show various embodiments of the invention as follows.

FIG. 1 is a schematic view of a prior-art metal shell.

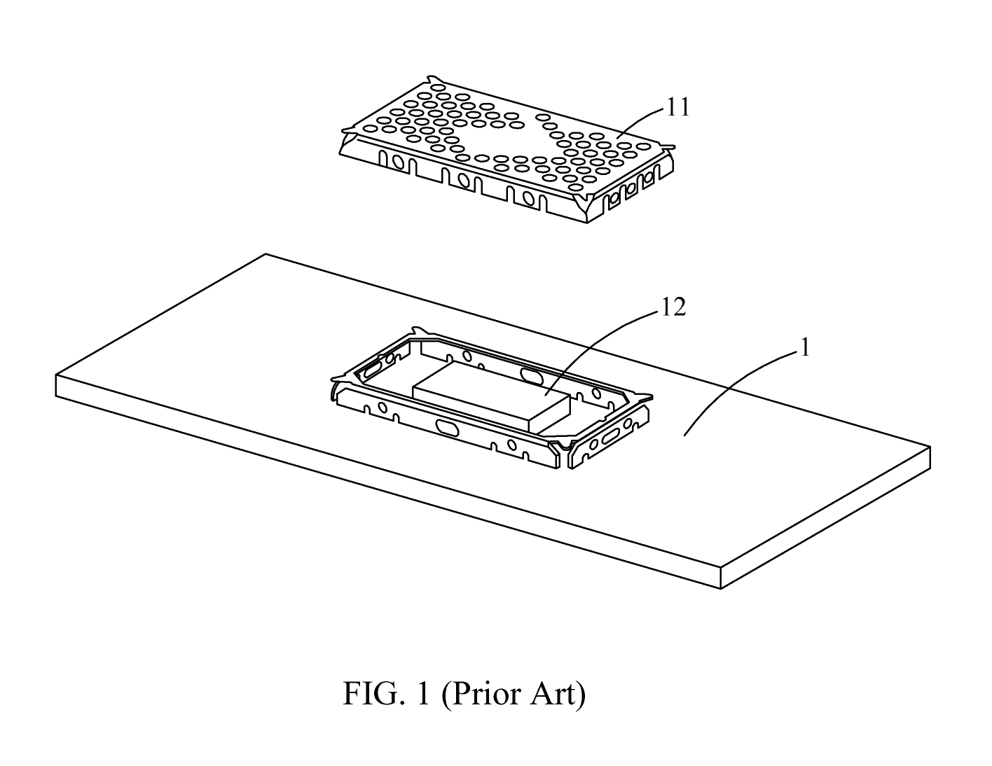

FIG. 2 is a schematic view of a prior-art IC shielding.

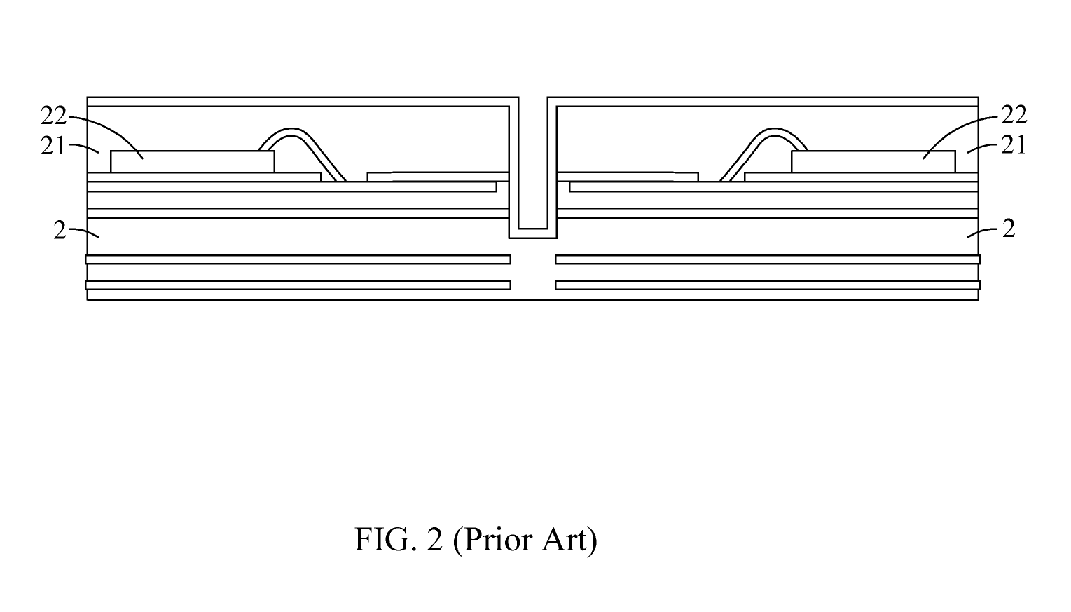

FIG. 3 is an IC shielding structure diagram of an embodiment of the method for manufacturing shielding according to the present invention.

FIG. 4 is a flow chart of an embodiment of the method for manufacturing shielding according to the present invention.

FIG. 5 is a flow chart of an embodiment of the method for manufacturing shielding according to the present invention.

FIG. 6 is a schematic view of an equipment of an embodiment of the method for manufacturing shielding according to the present invention.

### DETAILED DESCRIPTION OF THE PREFERRED EMBODIMENTS

The technical content of the present invention will become apparent by the detailed description of the following embodiments and the illustration of related drawings as follows.

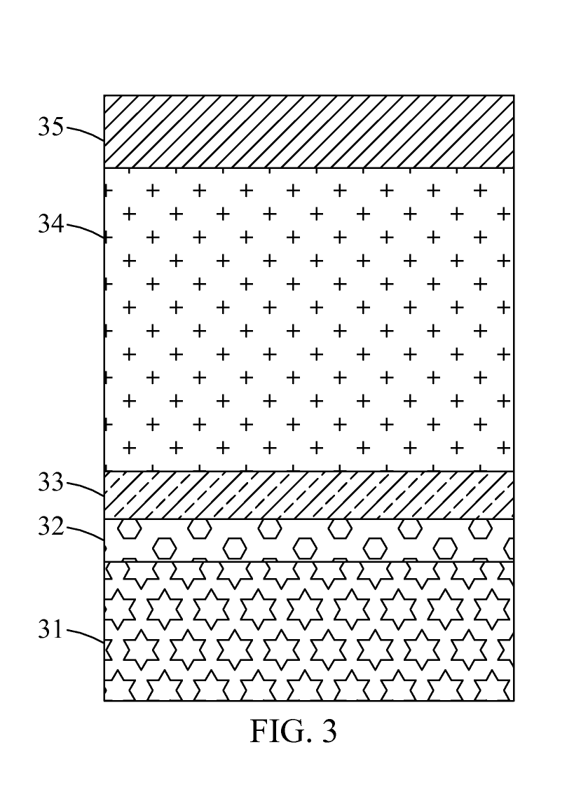

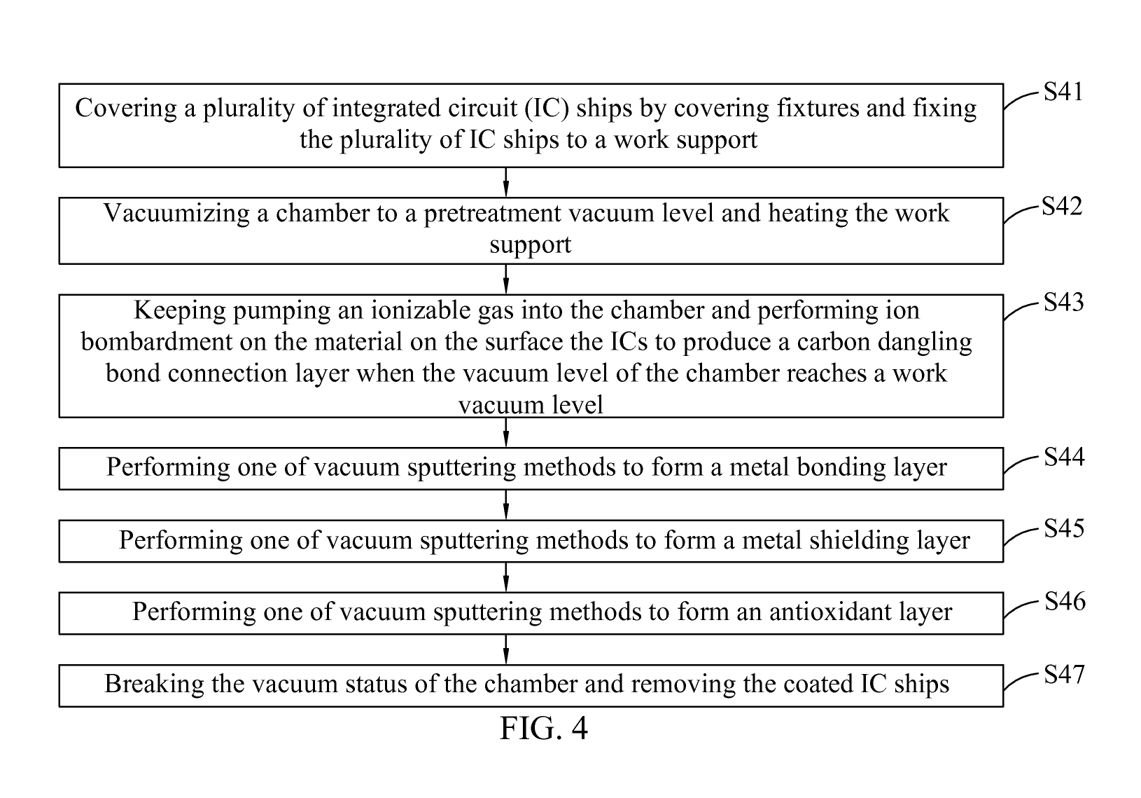

With reference to FIGS. 3 and 4 for an IC shielding structure diagram and a flow chart of an embodiment of the method for manufacturing shielding according to the present invention respectively.

The S41 comprises the following step: covering a plurality of integrated circuit (IC) chips by covering fixtures and fixing the plurality of IC chips to a work support.

The S42 comprises the following step: vacuumizing a chamber to a pretreatment vacuum level.

The S43 comprises the following step: keeping pumping an ionizable gas into the chamber and performing ion bombardment on material for IC packaging on the surface of the plurality of ICs in order to produce a carbon dangling bond connection layer on the material when the vacuum level of the chamber reaches a work vacuum level.

The S44 comprises the following step: performing one of vacuum sputtering methods to form a metal bonding layer on the carbon dangling bond connection layer.

The S45 comprises the following step: performing one of vacuum sputtering methods to form a metal shielding layer on the metal bonding layer.

The S46 comprises the following step: performing one of vacuum sputtering methods to form an antioxidant layer on the metal shielding layer.

The S47 comprises the following step: breaking the vacuum status of the chamber and removing the coated IC chips.

In the S41, IC chips need to be covered by covering fixtures for the vacuum sputtering process first. In the S42, the chamber needs to be vacuumized to a pretreatment vacuum level. In the S43, an ionizable gas first needs to be pumped into the chamber after the pretreatment vacuum level is reached. The ionizable gas may be argon (AR), etc. Next, the work support needs to be biased to transform the ionizable gas into plasma. Afterward the ion bombardment is performed for about 4˜6 minutes on the material 31 for IC packaging on the surface of the plurality of IC chips, which can break the carbon hydrogen bond or the carbonaceous bond of the material 31 on the surface of the IC chips and left the carbon dangling bond, such that the carbon dangling bond connection layer is formed. The aforementioned method can significantly strengthen the adhesive force between the metal layer and the plastic substrate and effectively prevent the coated metal layer form dropping off.

In the S44, the user keeps pumping the ionizable gas into the chamber to work as the working gas and the vacuum level of the chamber is kept being the work vacuum level. As shown in FIG. 3, the step is to perform the sputtering process by a metal target in order to form a metal bonding layer on the carbon dangling bond connection layer. The metal target may be a carbonatable metal material, such as Fe, Cr, Zr, Si, W or Ti, etc. In the meanwhile, a carbonic reaction gas needs to be pumped into the chamber so as to perform a vacuum sputtering process by a vacuum sputtering method. The vacuum sputtering method may be the middle frequency sputtering. The carbonic reaction gas may be C2H2 or CH4, etc.

The S45 is to form a metal shielding layer 34. As shown in FIG. 3, the metal shielding layer 34 is disposed on the metal bonding layer 33. High-conductivity metal needs to be coated on the metal bonding layer 33 in order to prevent electromagnetic interference (EMI), which could be Ag, Cu, Al or Cu—Ag, etc. The vacuum sputtering method for the metal shielding layer 34 may be the middle frequency sputtering or the multi-arc ion plating. The metal shielding layer 34 may be formed by a mixed sputtering method. The mixed sputtering method may be mixedly sputtering metal and non-mental, metals with different grain sizes or two different metals.

The next step is the S46. As shown in FIG. 3, the step is to form the antioxidant layer 35 on the metal shielding layer 34, which can effectively prevent the metal shielding layer 34 from being oxidized. In addition, the antioxidant layer 35 can have different colors according to actual requirements, which would be a good decoration for the IC chips. As shown in FIG. 3, the material of the antioxidant layer 35 may be metal, such as stainless steel (SUS), Ni, Sn, Cr or Ti, etc. The material of the antioxidant layer 35 may also be non-metal, such as TiC, TiN, TiCN, etc. The antioxidant layer 35 can be formed by the DC sputtering or the middle frequency sputtering.

The last step is the S47. The S47 is to break the vacuum status of the chamber and remove the coated IC chips.

It is worthy to point out that the prior method which forms the IC shielding layer on a plurality of IC chips attached on a circuit board requires an additional “pre-cutting” process. The “pre-cutting” process is used to cut the plurality of IC chips attached on a circuit board into single IC chips after the IC shielding is formed. On the contrary, the method according to the present invention can directly form the IC shielding layer on single IC chips without the “pre-cutting” process. The original manufacturing procedure will not be changed.

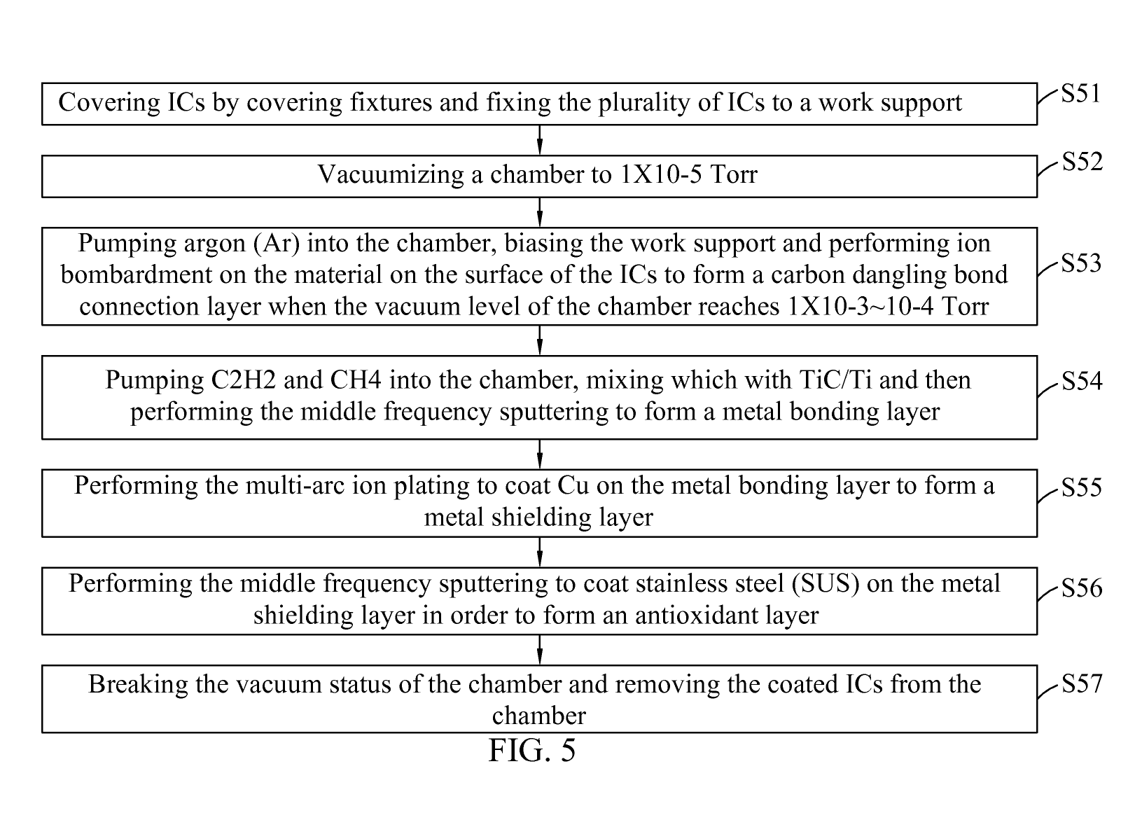

With reference to FIG. 5 for a flow chart of an embodiment of the method for manufacturing shielding according to the present invention.

The S51 comprises the following step: covering a plurality of IC chips by covering fixtures and fixing the plurality of IC chips to a work support.

The S52 comprises the following step: vacuumizing a chamber to 1×10⁻⁵ Torr.

The S53 comprises the following step: pumping argon (Ar) into the chamber, biasing the work support and performing ion bombardment on material for IC packaging on the surface of the plurality of IC chips to form a carbon dangling bond connection layer on the material when the vacuum level of the chamber reaches 1×10⁻³˜10⁻⁴ Torr.

The S54 comprises the following step: pumping C₂H₂ and CH₄.into the chamber, mixing which with TiC/Ti and then performing the middle frequency sputtering to form a metal bonding layer on the carbon dangling bond connection layer.

The S55 comprises the following step: performing the multi-arc ion plating to coat Cu on the metal bonding layer in order to form a metal shielding layer.

The S56 comprises the following step: performing the middle frequency sputtering to coat stainless steel (SUS) on the metal shielding layer in order to form an antioxidant layer.

The S57 comprises the following step: breaking the vacuum status of the chamber and removing the coated IC chips from the chamber.

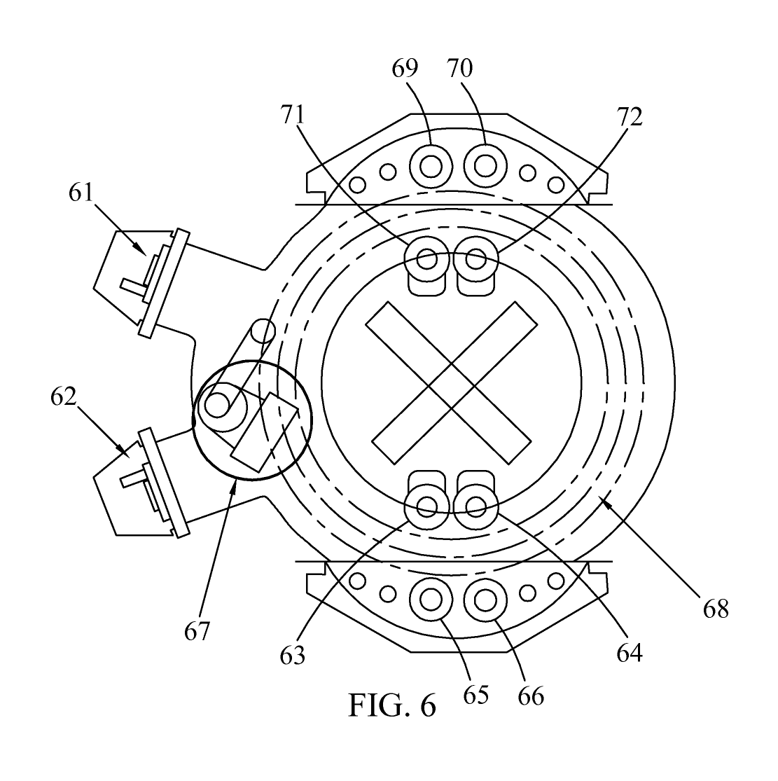

With reference to FIGS. 5 and 6 for a flow chart and a schematic view of an equipment of an embodiment of the method for manufacturing shielding according to the present invention respectively.

In the S51, a plurality of IC chips need to be covered by covering fixtures and then be fixed on a work support 68. A rotation axis is usually disposed on the work support 68. Fixtures are disposed on the rotation axis. The IC chips are disposed on the fixtures.

In the S52, the vacuum level of the chamber is vacuumized to 1×10⁻⁵ Torr.

In the S53, Argon is pumped into the chamber when the vacuum level of the chamber reaches 1×10⁻³˜10⁻⁴ Torr. Next, the work support 68 is biased by the work support transmission and bias system 67 and then the equipment perform ion bombardment on the material for IC packaging on the surface of the plurality of ICs to form a carbon dangling bond connection layer on the material.

In the S54, the work support transmission and bias system 67 transits the objects to be coated to the cylindrical targets 63 and 64. Afterward C2H2/CH4 are pumped into the chamber and mixed with TiC/Ti to perform the middle frequency sputtering and form a metal bonding layer through the cylindrical targets 63 and 64 (Ti target). The metal bonding layer is a gradation layer which can raise the adhesive force. Besides, the metal bonding layer can also be formed by using a multi-arc target to perform the multi-arc ion plating. The aforementioned is just for example and the present invention is not limited to such arrangement only.

In the S55, the work support transmission and bias system 67 moves the objects to be coated on the work support 68 to the three multi-arc targets 61. Next, the multi-arc ion planting is performed by the three multi-arc targets 61 to coat Cu on the metal bonding layer in order to form a metal shielding layer. The aforementioned process can also be performed by the four multi-arc targets 62, or using both of them at the same time. Similarly, the aforementioned process can be performed by the cylindrical target to perform the middle frequency sputtering, or by the multi-arc target and the cylindrical target to alternate to perform the multi-arc ion planting and the middle frequency sputtering in order to form the metal shielding layer by a mixed sputtering. For example, the middle frequency sputtering is performed by the cylindrical target (Cu target) 69, 70, 71 and 72 first. The working vacuum level of the chamber is kept at 4.8×10⁻¹ Pa. The working gas in the chamber is argon (Ar). The gas flow rate of the chamber is about 70˜100 sccm (Standard Cubic Centimeter Per Minute). The voltage of the cylindrical target 69, 70, 71 and 72 is 662V and the current of which is 8˜13 A. The frequency of the voltage applied on the cylindrical target 69, 70, 71 and 72 is 30˜50 KHz. The coating process lasts about 15˜30 minutes. After the coating process, the work support transmission and bias system 67 moves the work support 68 to the four multi-arc targets 62 to perform multi-arc ion planting. The working vacuum level of the chamber is kept at 1.7×10⁻⁰ Pa. The working gas is argon (Ar). The gas flow rate of the chamber is about 150˜120 sccm. The current of four multi-arc targets 62 is about 30˜50 A and the voltage of which is about 20 A. The coating process lasts about 15˜60 minutes. After the coating process, a Cu layer with coarse grains and fine grains is formed, which can be used as an EMI shielding layer. Similarly, the aforementioned step can also be performed by the two different metals or metal and non-metal.

In the S56, the objects to be coated on the work support 68 are moved to the cylindrical target 64, 65 by the work support transmission and bias system 67 in order to perform the middle frequency sputtering through the cylindrical target 64, 65 to coat stainless steel (SUS) or Ni over the metal shielding layer. Similarly, the middle frequency sputtering in the step can be replaced by the DC sputtering. The aforementioned is just for example and the present invention is not limited to such arrangement only.

The last step is the S57. The work support transmission and bias system 67 keeps rotating the work support 68 for several minutes to cool the work support 68 and then gas is pumped into the chamber to break the vacuum status of the chamber. Finally, the coated IC chips can be removed form the chamber.

It is worthy to point out that the number of the layer coated on the IC chips is not limited to three, which can vary with the actual requirements, and the present invention is not limited to such arrangement only.

In summation of the description above, the method for manufacturing shielding according to the present invention improves the problems that the prior-art metal shell is heavy, high-cost and unfavorable to thermal dissipation. In addition, the present invention can use multiple vacuum sputtering methods to directly form multiple structures with different functions, such like the EMI shielding layer and the antioxidant layer, etc., on a signal IC chip without the “pre-cutting” process. Thus, the original manufacturing procedure will not be changed. The method according to the present invention can change the vacuum sputtering method to perform the coating process according to actual situation, or alternate between multiple vacuum sputtering methods to perform the coating process, which is much flexible. Moreover, the method according to the present invention uses carbonatable metal and vacuum sputtering methods to form a gradation layer, such that the adhesion force between layers is much better than the prior-art.

While the means of specific embodiments in present invention has been described by reference drawings, numerous modifications and variations could be made thereto by those skilled in the art without departing from the scope and spirit of the invention set forth in the claims. The modifications and variations should in a range limited by the specification of the present invention.

What is claimed is:

1. A method for manufacturing IC shielding, comprising the following steps of:
covering a plurality of integrated circuit (IC) chips by covering fixtures and fixing the plurality of IC chips to a work support;
vacuumizing a chamber to a pretreatment vacuum level;
keeping pumping an ionizable gas into the chamber and performing ion bombardment on the material for IC packaging on the surface of the plurality of IC chips in order to produce a carbon dangling bond connection layer on the material when the vacuum level of the chamber reaches a work vacuum level;
performing multiple vacuum sputtering methods to form a first coating layer and a second coating layer on the carbon dangling bond connection layer; and
breaking the vacuum status of the chamber and removing the coated IC chips.

2. The method for manufacturing IC shielding of claim 1, wherein the multiple vacuum sputtering methods comprise the middle frequency sputtering, the direct current (DC) sputtering or the multi-arc ion plating.

3. The method for manufacturing IC shielding of claim 2, wherein the first coating layer is a metal bonding layer formed by the middle frequency sputtering or the multi-arc ion plating.

4. The method for manufacturing IC shielding of claim 2, wherein the second coating layer is a metal shielding layer formed by the middle frequency sputtering or the multi-arc ion plating.

5. The method for manufacturing IC shielding of claim 4, wherein the metal shielding layer is formed by a mixed sputtering which alternates the middle frequency sputtering and the multi-arc ion plating.

6. The method for manufacturing IC shielding of claim 5, wherein the mixed sputtering comprises mixedly sputtering metal and non-mental, mixedly sputtering metals with different grain sizes or mixedly sputtering two different metals.

7. The method for manufacturing IC shielding of claim 2, further comprising the following step of:
forming a third coating layer on the second coating layer by the multiple vacuum sputtering methods.

8. The method for manufacturing IC shielding of claim 7, wherein the third coating layer is an antioxidant layer formed by the DC sputtering or the middle frequency sputtering.

9. The method for manufacturing IC shielding of claim 1, wherein the ionizable gas is argon (AR).

10. The method for manufacturing IC shielding of claim 1, wherein the pretreatment vacuum level is 1×10⁻⁵ Torr.

11. The method for manufacturing IC shielding of claim 1, wherein the work vacuum level is 1×10⁻³˜10⁻⁴ Torr.
